(19) United States
(12) Patent Application Publication
(10) Pub. No.: US 2026/0221527 A1
(43) Pub. Date: Jul. 30, 2026

(54) POWER SUPPLY UNIT

(71) Applicant: SKYRORA LIMITED, Cumbernauld (GB)

(72) Inventors: Hanna Ziubrii, Cumernauld (GB); Oleksandr Taran, Cumbernauld (GB)

(21) Appl. No.: 19/146,626

(22) PCT Filed: Jan. 12, 2024
(86) PCT No.: PCT/GB2024/050077

§ 371 Date: Jul. 9, 2025

(30) Foreign Application Priority Data
Jan. 12, 2023 (GB) 2300467.4

(51) Int. Cl. H01M 10/42; B64G 1/42; G01R 31/385; H01M 10/052; H01M 50/224; H01M 50/24; H01M 50/242; H01M 50/249; H02J 7/44

(52) U.S. Cl. CPC H01M 10/425; B64G 1/425; G01R 31/385; H01M 10/052; H01M 50/224; H01M 50/24; H01M 50/242; H01M 50/249; H02J 7/44; H01M 2010/4271; H01M 2010/4278; H01M 2220/20

(57) ABSTRACT

A power supply unit for a launch vehicle is disclosed. The power supply unit comprises a protective housing and, within the housing, a control module and a battery holder configured to receive a plurality of replaceable lithium-ion battery cells. The control module comprises a power switching and distribution module, and a battery management and monitoring system module. The power supply unit has several advantages including improved safety, and reduced size and weight.

The present invention relates to a power supply unit, particularly, although not exclusively, for use in launch vehicles.

### BACKGROUND TO THE INVENTION

Within the burgeoning small satellite market there is a growing demand for launch vehicles to place payloads into orbit and provide access to space for missions including Earth observation, communication and navigation, amongst many more. The Applicant has recently performed a full ground test of its unique 70 kN rocket engine, marking a key milestone in the developments of its proprietary XL orbital vehicle which will use the rocket engine in its first and second stages. However, propulsion is only one consideration in the provision of cost-effective and responsive access to space; the small space industry requires innovation in a wide range of technical fields and areas of technology to lower the barrier to entry for commercial spaceflight activities. This includes providing reliable and economic power supply units.

A power supply unit is a device, or set of devices, for the production and distribution of electricity. In the field of launch vehicles, particularly those which use electro-automation, the power supply unit is an integral part.

To organise pre-launch preparation and launch, it is necessary to combine ground power supply systems and on-board power systems with minimal switching transients.

A typical onboard power supply circuit in an airborne launch vehicle 1 is shown in FIG. 1. The launch vehicle 1 comprises one or more battery cells 2 in electrical communication with a power distribution unit 3. One or more power consumers 4, and optionally one or more high priority consumers 5, are in electrical communication with the power distribution unit 3. Distribution of power to the consumers 4,5 is controlled by one or more switches 6 in the power distribution unit 3.

The power distribution unit 3 is also in electrical communication with a ground power supply 7. The switches 6 selectively control whether power is derived from the one or more battery cells 2, or from the ground power supply 7.

However, there are various problems associated with power supply units for launch vehicles in the art; namely to do with size, weight, and/or protection from external influences.

Power supply units in the art include those described in CN108306384 A, US2007/188137 A1, CN217347551 U, US2015/107094 A1, U.S. Pat. No. 8,703,319 B1, and U.S. Pat. No. 5,763,116 A.

### SUMMARY OF THE INVENTION

There is generally a need for an apparatus and method which addresses one or more of the problems identified above. Further aims and objects of the invention will become apparent from reading the following description.

According to a first aspect of the invention, there is provided a power supply unit for a launch vehicle comprising a protective housing and, within the housing, a control module and a battery holder configured to receive a plurality of replaceable lithium-ion battery cells, wherein the control module comprises a power switching and distribution module, and a battery management and monitoring system (BMS) module.

The inventors have found the power supply unit of the present invention to have several advantages over the prior art. By having a housing which combines a battery holder and control module, as well as having pressure resistance (from the protective housing) and, optionally, charge protection, the overall safety of the power supply unit is enhanced. Additionally, the power supply unit of the present invention advantageously has a reduced size and weight compared to conventional power supply units, which is particularly important in launch vehicles. This is because the combined battery holder and control module reduces the quantity of cables required between components. To minimise space, the control module may be positioned adjacent to a surface of the battery holder, preferably adjacent to the largest surface of the battery holder.

The protective housing protects the components of the power supply unit from external influence. More specifically, the protective housing permits the power supply unit to be suitable for operation in a vacuum, and able to withstand wide temperature ranges, vibrational loads, static charge and/or short circuit (which launch vehicles are typically subjected to). The protective housing also protects the components of the power supply unit from solar rays.

In summary, by providing a plurality of components (i.e. battery holder, power switching and distribution module, and BMS module) within a housing, a synergistic effect is realised which provides an improved power supply unit compared to the prior art.

While the power supply unit of the present invention is of particular use in a launch vehicle, the inventors have found that the power supply unit can be used anywhere that a reliable source of power is required. Therefore, application of the present invention is not explicitly limited to a launch vehicle.

Preferably, the battery holder comprises a plurality of lithium-ion battery cells. Most preferably, the battery holder comprises eight lithium-ion battery cells.

The one or more lithium-ion battery cells may preferably comprise one or more lithium iron phosphate (LiFePO₄) battery cells. The lithium iron phosphate battery cells are fire and explosion proof, and the inventors have found them to be particularly efficacious in a power supply unit for use in a launch vehicle. To the best of the Applicant's knowledge, lithium iron phosphate battery cells have not hitherto been used in launch vehicle applications. Preferably, all the one or more lithium-ion battery cells are lithium iron phosphate (LiFePO₄) battery cells.

The one or more lithium-ion battery cells may comprise one or more lithium manganese oxide (e.g. LiMn₂O₄) battery cells. The one or more lithium-ion battery cells may comprise one or more lithium nickel manganese cobalt oxide (e.g. LiNiMnCoO₂) battery cells. The one or more lithium-ion battery cells may comprise one or more lithium nickel cobalt aluminium oxide (e.g. LiNiCoAlO₂) battery cells. The one or more lithium-ion battery cells may comprise one or more lithium nickel cobalt manganese aluminium oxide battery cells. The one or more lithium-ion battery cells may comprise one or more lithium cobalt oxide (e.g. LiCoO₂) battery cells.

The one or more lithium-ion battery cells may comprise one or more lithium-ion polymer battery cells.

The housing may be made of an anodised metal. The anodised metal may be anodised aluminium. The inventors have found anodised metal, particularly anodised aluminium, to provide improved protection to the components of the power supply unit.

Preferably, the battery holder is configured to arrange battery cells in series. Preferably, the battery holder has an 8S1P configuration. Most preferably, the battery holder is configured to receive 8 battery cells.

Most preferably, the battery holder is arranged such that the battery cells are replaceable, thus advantageously prolonging the lifetime of the power supply unit.

The power supply unit may provide a DC discharge current.

The power supply unit may comprise a microcontroller. The microcontroller may be a STM32, preferably STM32F4, series microcontroller. STM32 series microcontrollers are available from STMicroelectronics™.

The power supply unit preferably permits (re) charging the one or more battery cells. Thus, in some embodiments, the power supply unit comprises means for (re) charging the one or more battery cells.

The power supply unit, preferably the BMS module, may provide an interface between the one or more battery cells and a charge line. The charge line can be used to (re) charge the battery cells.

The battery cells of the power supply unit preferably can be charged in situ in the launch vehicle. This advantageously means that the power supply unit does not require dismantling (or disassembling) from the launch vehicle for charging.

Preferably, the power supply unit can provide power (to one or more power consumers) while simultaneously charging all of the battery cells.

The BMS module may comprise means for balancing the battery cells. This advantageously prolongs the life of the battery cells and increases the efficiency of the power reserve.

The power supply unit, preferably the BMS module, may comprise means for providing overcharge protection.

The power supply unit may comprise one or more, optionally two, interface circuits for external data exchange and/or for remote control of the power supply unit. The interface circuit may be a RS485 interface.

The power supply unit may comprise a plurality of connectors for connecting the power supply unit to power consumers.

One or more of the connectors may be for connecting the power supply unit to high priority power consumers.

The power supply unit, preferably the power switching and distribution module, may be connectable to a ground power supply.

The power supply unit, preferably the power switching and distribution module, May comprise a switch for switching between the battery cells and the ground power supply. This advantageously means that while on the ground, the power supply unit can draw power from the ground power supply (rather than from the battery cells), maximising available power from the battery cells once the launch vehicle is airborne. The power supply unit may advantageously be able to switch from the ground power supply to the battery cells (and vice versa) without affecting the operation of the consumers.

The power supply unit, preferably the power switching and distribution module, may comprise at least two power lines (i.e. power buses): a main power line and a reserve power line. For the avoidance of doubt, the terms “power line” and “power bus” are used interchangeably.

The power supply unit may comprise a switch for switching from the main power line to the reserve power line when a fault (or failure) is detected, such as a short circuit or line break. The inventors have found that this arrangement advantageously provides a guaranteed and uninterrupted power supply because, in the event of a fault (more specifically, detection of a fault), the power supply unit can very quickly (preferably instantaneously) switch to the reserve power line. In some embodiments, the maximum switching time from the main power line to the reserve power line (in the case of a power failure in one of the buses) is less than about 5 ms, or less than about 4 ms, or less than about 3 ms, or about 2 ms. In some embodiments, in the case of a short circuit in the power bus, the switch delay time of consumer is less than about 1 msec, or about 0.5 msec.

The power supply unit may comprise at least one switch between the main power line (and optionally the reserve power line) and each of the aforementioned connectors (for connecting the power supply unit to power consumers). A purpose of the switch is to rapidly disconnect a consumer from the power supply unit if a fault in that consumer is detected, thus preserving the operability of the remaining consumers. In some embodiments, each connector has two switches associated with it; one to the main power line, and one to the reserve power line.

The power supply unit, preferably the BMS module, may comprise one or more sensors suitable for measuring one or more of current, voltage, and temperature.

The power supply unit, preferably the BMS module, may be configured to measure one or more of total voltage of power lines; total current of battery cells; total voltage of battery cells; and current of consumer lines.

The power supply unit may have a weight of less than about 10 kg, or less than about 9 kg, or less than about 8 kg, or less than about 7 kg, or about 6 kg. The power supply unit of the present invention advantageously has a comparatively lower weight than power supply units in the art, when considering the power supply unit of the present invention comprises the control module. In other words, while the power supply unit of the present invention may have a similar weight to power supply units in the art, these do not include a control module.

The power supply unit may operate autonomously or, alternatively, may operate under manual control.

According to a second aspect of the invention, there is provided a power supply network comprising a plurality of connected power supply units according to the first aspect.

By providing a plurality of connected power supply units, in the event of a fault or failure of one of the power supply units, power can still be provided to consumers. This results in a guaranteed and uninterrupted power supply.

The plurality of power supply units may be connected via the main (and optionally reserve) power lines.

Preferably, the power supply network comprises two power supply units.

The power supply network may have a weight of less than about 20 kg, or less than about 18 kg, or less than about 16 kg, or less than about 14 kg, or less than about 12 kg, or less than about 10 kg.

Embodiments of the second aspect of the invention may include one or more features of the first aspect of the invention or its embodiments, or vice versa.

According to a third aspect of the invention, there is provided a use of a power supply unit according to the first aspect, or a power supply network according to the second aspect, in a launch vehicle.

Embodiments of the third aspect of the invention may include one or more features of the first or second aspects of the invention or their embodiments, or vice versa.

According to a fourth aspect of the invention, there is provided a launch vehicle comprising a power supply unit according to the first aspect, or a power supply network according to the second aspect.

Embodiments of the fourth aspect of the invention may include one or more features of the first to third aspects of the invention or their embodiments, or vice versa.

According to a fifth aspect of the invention, there is provided a method of manufacturing a power supply unit, comprising the steps of:
providing a protective housing; and
within the housing, providing a control module and a battery holder configured to receive one or more, preferably eight, battery cells.

Preferably, the method is for manufacturing a power supply unit according to the first aspect.

Embodiments of the fifth aspect of the invention may include one or more features of the first to fourth aspects of the invention or their embodiments, or vice versa.

According to a sixth aspect of the invention, there is provided a power supply unit for a launch vehicle comprising a protective housing and, within the housing, a control module and a battery holder configured to receive one or more replaceable battery cells.

Embodiments of the sixth aspect of the invention may include one or more features of the first to fifth aspects of the invention or their embodiments, or vice versa.

Although not so limited, in any of the preceding aspects of the invention the power supply unit is preferably for use in a launch vehicle, and most preferably a launch vehicle for carrying a payload such as a spacecraft or a satellite from the surface of the Earth to space.

### BRIEF DESCRIPTION OF THE DRAWINGS

There will now be described, by way of example only, various embodiments of the invention with reference to the drawings, of which:

FIG. 1 is a power supply circuit in an airborne launch vehicle of the prior art;

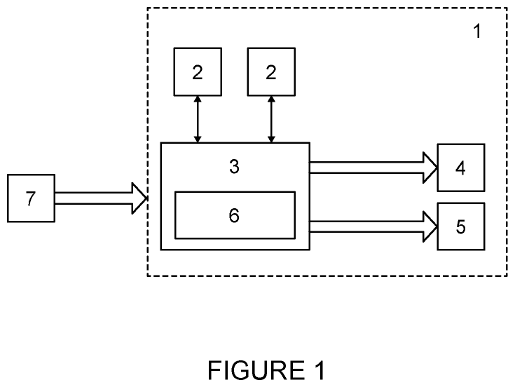

FIG. 2 is a schematic of a power supply unit according to an embodiment of the present invention;

FIG. 3 is a cutaway perspective view of a power supply unit according to an embodiment of the present invention; and

FIG. 4 is a perspective view of a power supply unit according to an embodiment of the present invention.

### DETAILED DESCRIPTION OF THE PREFERRED EMBODIMENTS

### Power Supply Unit

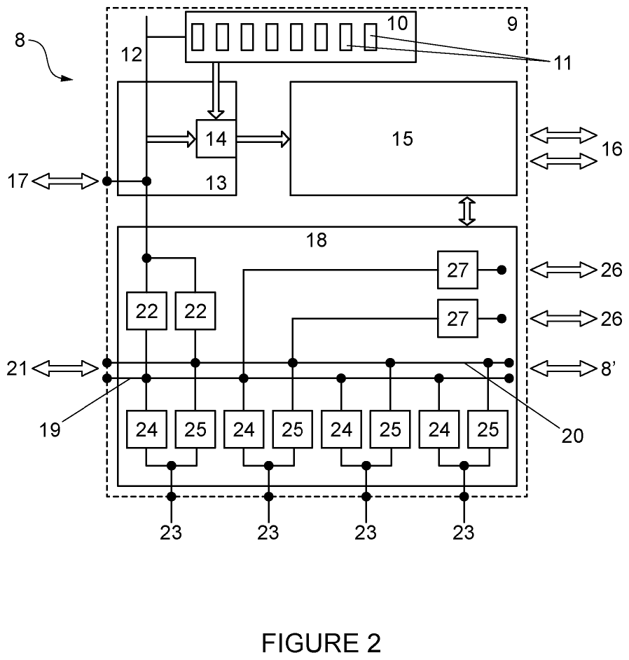

A power supply unit 8 according to an embodiment of the present invention, in the form of a schematic, is shown in FIG. 2. The power supply unit comprises a housing 9 which, within the housing 9, comprises all the components of the power supply unit 8.

The power supply unit comprises a battery holder 10 having a plurality of replaceable battery cells 11. While it is preferred that the battery cells are replaceable, the present invention is not limited as such. In this embodiment, the battery holder 10 comprises eight LiFePO₄ battery cells 11 in an 8S1P configuration. LiFePO₄ battery cells are fire and explosion proof, which makes them of particular benefit in a launch vehicle. Instead, battery failure would be through a leak (rather than an explosion), which is safer in launch vehicle applications because a battery leak produces no flames. However, the present invention is not explicitly limited to LiFePO₄ battery cells, and it will be appreciated that the type of battery cell 11 may be dependent on the specific application and would be apparent to the skilled person. For example, one or more of the battery cells may be lithium manganese oxide (e.g. LiMn₂O₄) battery cells, lithium nickel manganese cobalt oxide (e.g. LiNiMnCoO₂) battery cells, lithium nickel cobalt aluminium oxide (e.g. LiNiCoAlO₂) battery cells, lithium nickel cobalt manganese aluminium oxide battery cells, lithium cobalt oxide (e.g. LiCoO₂) battery cells, or lithium-ion polymer battery cells. Additionally, the present invention is not explicitly limited to an 8S1P configuration, and the specific configuration of the battery cells 11 may be dependent on the specific application and would be apparent to the skilled person.

Electrically connected to the battery holder 10 (and thus to the battery cells 11) via a bus 12 is a battery management and monitoring system (BMS) module 13. The BMS module 13 comprises a measuring and data processing device 14, which comprises sensors for measuring the voltage of each battery cell 11, and for measuring the current through the bus 12. This is denoted by the arrow from the battery holder 10 to the measuring and data processing device 14. It will be appreciated that other parameters pertaining to current, voltage, and/or temperature may be measured. Data from the measuring and data processing device 14 is subsequently transmitted to a microcontroller 15. Connected to the microcontroller 15 are two RS485 interface circuits 16 for external data exchange, and remote monitoring and control. While this embodiment uses RS485 interface circuits, any suitable interface circuit for external data exchange and/or remote monitoring and control may be used.

Additionally, in some embodiments the BMS module 13 comprises means for balancing the battery cells 11, and in some embodiments the BMS module 13 comprises means for providing overcharge protection.

Electrically connected to the BMS module 13 via the bus 12 is a charge line 17. The purpose of the charge line 17 is to charge the battery cells 11 in the battery holder 10, preferably in situ in the launch vehicle. The BMS module 13 provides an interface between the battery cells 11 and the charge line 17. The BMS module 13 is configured such that it automatically disconnects the charge line 17 when the pre-set voltage threshold is reached. Additionally, in this embodiment, the power supply unit 8 is arranged such that it can provide power while simultaneously charging the battery cells 11.

Electrically connected to the BMS module 13 via the bus 12 is a power switching and distribution module 18, which performs the main control of the power supply unit 8. In particular, the power switching and distribution module 18 is responsible for providing consumer distribution.

The power switching and distribution module 18 comprises a main power bus 19 and a reserve power bus 20, both of which are connected to bus 12 and are connectable to a ground power supply 21. It will be appreciated that the power switching and distribution module 18 may comprise one or more further power buses, to provide for added redundancy.

Between the main 19 and reserve 20 power buses and the BMS module 13 are two switches 22 for controlling whether the main 19 and reserve 20 power buses draw power from the battery cells 11 in the battery holder 10 or from the ground power supply 21. Thus, the power switching and distribution module 18 is responsible for switching between ground power 21 and onboard battery cells 11.

Connected to the main 19 and reserve 20 power buses are four power consumers 23, which draw power from the power supply unit 8. However, it will be appreciated that the number of power consumers 23 need not be limited to four and can be any suitable number.

Positioned between each power consumer 23 and the main 19 and reserve 20 power buses are a pair of switches 24,25; one switch 24 is positioned between the power consumer 23 and the main power bus 19, and the other switch 25 is positioned between the power consumer 23 and the reserve power bus 20.

Also connected to the main 19 and reserve 20 power buses are one or more high priority consumers 26. The high priority consumers 26 typically have a lower power requirement than the aforementioned power consumers 23 (for example, 5 A compared to 30 A). Between the main power bus 19 and the high priority consumers 26, and between the reserve power bus 20 and the high priority consumers 26, is a protection circuit 27.

Thus, the power supply unit 8 has two levels of consumer connection: first, priority lines of low-current consumers 26 with guaranteed connection to the main power bus 19; and second, distributed power lines for more powerful consumers 23.

In an embodiment, the power supply unit has one or more, or all, of the following technical characteristics:
An output current of up to 65 A continuous, and a peak current of up to 100 A (10 sec);
A nominal voltage of 24 VDC and a voltage range of 16-32 VDC;
A typical charge of 8 A (1 C, 5 C);
An operation temperature from −40° C. (preferably from −20° C.) to +85° C.;
A weight of about 6 kg.

In an embodiment, the power supply unit has five high priority (low power) consumer lines (bus) at 5 A each, and four power consumer lines (bus) at 30 A each.

In some embodiments, the power supply unit operates autonomously. In some embodiments, the power supply unit operates under manual control.

To provide a guaranteed power supply network, a second power supply unit 8′ can be connected to the first power supply unit 8. In some embodiments, the second power supply unit 8′ is connected to the first power supply unit 8 via the main 19 and reserve 20 power buses. Therefore, in the instance of a fault or failure in the first power supply unit 8, the power consumers 23 can still receive power via the second power supply unit 8′.

The second power supply unit 8′ can be the same, or similar to, the first power supply unit 8, or can be different to provide for added redundancy.

In some embodiments, the power supply network has a weight of less than about 20 kg, or less than about 18 kg, or less than about 16 kg, or less than about 14 kg, or less than about 12 kg, or less than about 10 kg.

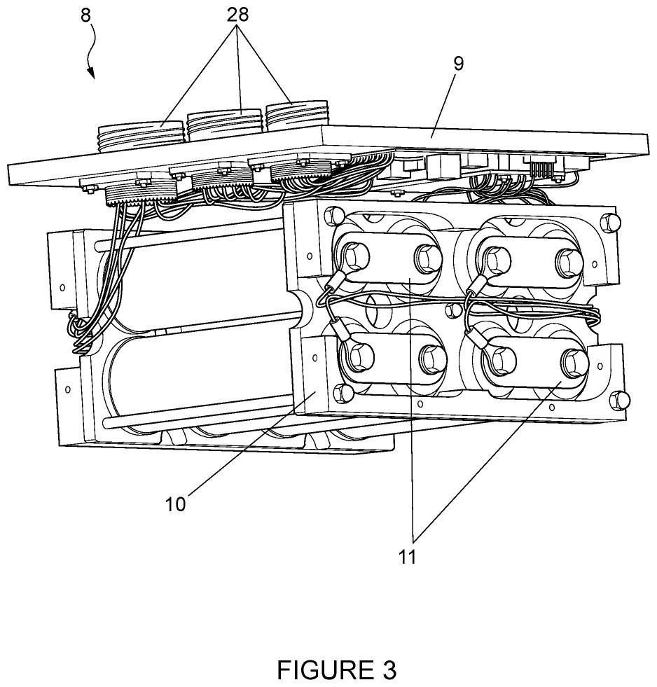

FIG. 3 shows a cutaway perspective view of a power supply unit 8 according to an embodiment of the present invention. The power supply unit 8 comprises a battery holder 10 having a plurality of replaceable battery cells 11. While it is preferred that the battery cells are replaceable, the present invention is not limited as such. In this embodiment, the battery holder 10 comprises eight LiFePO₄ battery cells 11 in an 8S1P configuration.

Connected to the battery cells 11 is the circuitry associated with the control module. The features of the control module have been described in more detail above with respect to FIG. 2.

Also shown is a single face of the housing 9, and a plurality of connectors 28 for connecting the power supply unit 8 to power consumers 23. It will be appreciated that any suitable number of connectors 28 can be used.

### Housing

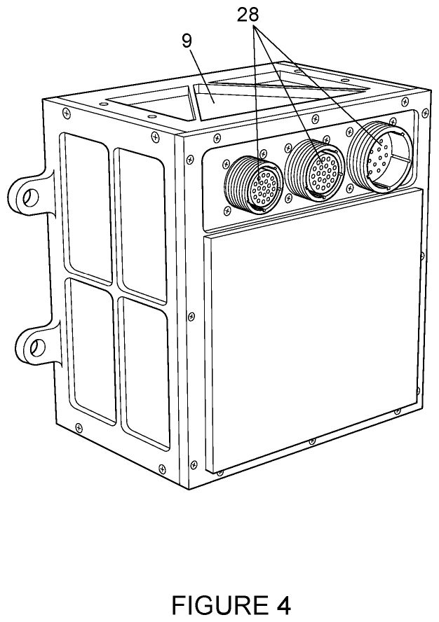

FIG. 4 shows a housing 9 according to an embodiment of the present invention. The housing 9 has a generally cuboid shape and is made from anodised aluminium which ensures protection from external influences. Additionally, all internal connections within the housing 9 were made with flammable-proof wires (not visible). It will be appreciated that the housing 9 need not be limited to a cuboid and can have any suitable shape.

Also shown is a plurality of connectors 28 for connecting the power supply unit 8 to power consumers 23. It will be appreciated that any suitable number of connectors 28 can be used.

### Critical External Influence Testing

To demonstrate the effectiveness of the power supply unit, the working capacity of the power supply unit under critical external influence was obtained. The data is shown in Tables 1 and 2.

TABLE 1
Critical external influence testing

| Type of test | Standard ISO/IEC | Values |
|---|---|---|
| Exposure to high | IEC 60068-2-14 | Change of temperature up- |
| ambient temperatures | Environmental testing-Part 2- | 40 to +85° C. |
| | 14: Tests-Test N: Change of | Exposure time 3 hr. |
| | temperature | Measure after the |
| | | stabilisation period |
| Exposure to lower | IEC 60068-2-14 | Change of temperature up- |
| ambient temperatures | Environmental testing-Part 2- | 40 to +85° C. |
| | 14: Tests-Test N: Change of | Exposure time 3 hr. |
| | temperature | Measure after the |
| | | stabilisation period |
| Vibration resistance test | IEC 60068-2-6 Environmental | See Table 2 |
| | testing-Part 2-6: Tests-Test: | Duration is 2.5 min/axis for |
| | Vibration (sinusoidal) | each one |
| | IEC 60068-2-64 | |
| | Environmental testing-Part 2- | |
| | 64: Tests-Test: Vibration, | |
| | broadband random and | |
| | guidance | |
| Linear acceleration test | IEC 60068-2-7 Acceleration, | Degree of rigidity 1 |
| | steady state | (10 g) for 3 minutes |
| | | perpendicular and parallel |
| | | to the mounting plane |
| Low Air Pressure test | IEC 60068-2 Basic | 10⁻¹ mm Hg. |
| (vacuum) | environmental testing | Exposure time 1 hr |
| | procedures Part 2-13: Tests- | |
| | Test M: Low air pressure | |
| Fast burst immunity test | IEC 61000-4-4 | Level 3 |
| | Electromagnetic compatibility | |
| | (EMC)-Part 4-4: Testing and | |
| | measurement techniques- | |
| | Electrical fast transient/burst | |
| | immunity test | |
| Voltage and current | IEC 61000-4-5 | Level 3 |
| surge immunity test | Electromagnetic compatibility | |
| | (EMC)-Part 4-5: Testing and | |
| | measurement techniques- | |
| | Surge immunity test | |
| Electrostatic discharge | IEC 61000-4-2 | Level 3 |
| immunity test (ESD) | Electromagnetic compatibility | |
| | (EMC)-Part 4-2: Testing and | |
| | measuring techniques- | |
| | Electrostatic discharge | |
| | immunity test. | |
| Radiofrequency | IEC 61000-4-3 Part 4-3: | Level 3 |
| electromagnetic | Testing and measurement | |
| immunity test | techniques-Radiated, | |
| | radiofrequency, | |
| | electromagnetic field immunity | |
| | test method | |
| Power frequency | IEC 61000-4-8 | Level 3; 50 Hz |
| magnetic field immunity | Electromagnetic compatibility | |
| test | (EMC)-Part 4-8: Testing and | |
| | measurement techniques- | |
| | Power frequency magnetic | |
| | field immunity test | |

TABLE 2
Sinusoidal and random vibration test levels

| | Perpendicular to | | | Parallel to | | |
|---|---|---|---|---|---|---|
| | mounting plane | | | mounting plane | | |
| | Frequency | | | Frequency | | |
| | range | | | range | | |
| | (Hz) | Amplitude | | (Hz) | Amplitude | |
| Sine | 5-21 | ±11,00 | mm | 5-21 | ±11,00 | mm |
| vibration | 21-60 | 20,00 | g | 21-60 | 20,00 | g |
| | 60-100 | 6,00 | g | 60-100 | 6,00 | g |
| Random | 20-100 | +3,00 | dB/oct | 20-100 | +3,00 | dB/oct |
| vibration | 100-300 | 0.12 | g²/Hz | 100-300 | 0,12 | g²/Hz |
| | 300-2000 | −5.00 | dB/oct | 300-2000 | −5,00 | dB/oct |

As can be seen, the power supply unit of the present invention meets many of the industry standard requirements.

As discussed previously, the power supply unit of the present invention has numerous advantages, particularly with respect to improved safety, and reduced size and weight. Furthermore, the power supply unit of the present invention is an improved guaranteed provider of power. This is because the power supply unit provides a plurality of backups and reserves—such as, a plurality of battery cells; a plurality of power lines (main and reserve); and a plurality of power supply units in a power supply network.

A power supply unit 8 for a launch vehicle is disclosed. The power supply unit 8 comprises a protective housing 9 and, within the housing 9, a control module and a battery holder 10 configured to receive a plurality of replaceable lithium-ion battery cells 11. The control module comprises a power switching and distribution module 18, and a battery management and monitoring system module 13. The power supply unit 8 has several advantages including improved safety, and reduced size and weight.

Throughout the specification, unless the context demands otherwise, the terms “comprise” or “include”, or variations such as “comprises” or “comprising”, “includes” or “including” will be understood to imply the inclusion of a stated integer or group of integers, but not the exclusion of any other integer or group of integers. Furthermore, unless the context clearly demands otherwise, the term “or” will be interpreted as being inclusive not exclusive.

The foregoing description of the invention has been presented for purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention as defined by the appended claims.

1. A power supply unit for a launch vehicle comprising a protective housing and, within the housing, a control module and a battery holder configured to receive a plurality of replaceable lithium-ion battery cells,
wherein the control module comprises a power switching and distribution module, and a battery management and monitoring system module.

2. The power supply unit according to claim 1, wherein the power supply unit has a weight of less than about 10 kg.

3. The power supply unit according to claim 1 or 2, wherein the plurality of lithium-ion battery cells comprises one or more lithium iron phosphate battery cells.

4. The power supply unit according to claim 3, wherein the battery holder comprises eight lithium iron phosphate battery cells.

5. The power supply unit according to claim 1, wherein the housing is made of anodised aluminium.

6. The power supply unit according to claim 1, wherein the power supply unit comprises a microcontroller.

7. The power supply unit according to claim 1, wherein the power supply unit comprises means for charging the one or more battery cells.

8. The power supply unit according to claim 7, wherein the power supply unit provides an interface between the one or more battery cells and a charge line.

9. The power supply unit according to claim 7, wherein the battery cells of the power supply unit can be charged in situ in the launch vehicle.

10. The power supply unit according to claim 1, wherein the power supply unit comprises one or more interface circuits for external data exchange.

11. The power supply unit according to claim 1, wherein the power supply unit comprises a plurality of connectors for connecting the power supply unit to power consumers, and wherein one or more of the connectors are for connecting the power supply unit to high priority power consumers.

12. (canceled)

13. The power supply unit according to claim 1, wherein the power supply unit is connectable to a ground power supply.

14. The power supply unit according to claim 1, wherein the power supply unit comprises a switch for switching between the battery cells and the ground power supply.

15. The power supply unit according to claim 14, wherein the power supply unit comprises at least two power lines: a main power line and a reserve power line.

16. The power supply unit according to claim 14, wherein the power supply unit comprises a switch for switching from the main power line to the reserve power line when a fault is detected.

17. The power supply unit according to claim 1, wherein power supply unit comprises one or more sensors suitable for measuring one or more of current, voltage, and temperature.

18. The power supply unit according to claim 16, wherein the power supply unit is configured to measure one or more of total voltage of power lines; total current of battery cells; total voltage of battery cells; and current of consumer lines.

19. A power supply network comprising a plurality of connected power supply units according to claim 1.

20. Use of a power supply unit according to claim 1, or a power supply network in a launch vehicle.

21. A launch vehicle comprising a power supply unit according to claim 18, or a power supply network.
